(19) United States
(12) Patent Application Publication
(10) Pub. No.: US 2021/0357008 A1
(43) Pub. Date: Nov. 18, 2021

(54) INTEGRATED MODULE AND DISPLAY EQUIPMENT

(71) Applicant: Beijing Xiaomi Mobile Software Co., Ltd., Beijing (CN)

(72) Inventors: Yihui ZHOU, Beijing (CN); Xuan LI, Beijing (CN); Shihwei LU, Beijing (CN)

(73) Assignee: Beijing Xiaomi Mobile Software Co., Ltd.

(21) Appl. No.: 17/144,922

(22) Filed: Jan. 8, 2021

(30) Foreign Application Priority Data
May 18, 2020 (CN) 202010419239.8

(51) Int. Cl. G06F 1/18; G06F 1/16

(52) U.S. Cl. CPC G06F 1/189; G06F 1/1605

(57) ABSTRACT

An integrated module includes: a module housing having a transmission hole; an audio input component located in the module housing; and an integrated component located in the module housing, the integrated component comprising multiple functional devices of different types; wherein the transmission hole is provided for a transmission line that establishes an electrical connection with at least one of the audio input component or the integrated component to pass through.

### CROSS-REFERENCE TO RELATED APPLICATIONS

This application is based on and claims priority to Chinese Patent Application No. 202010419239.8 filed on May 18, 2020, the content of which is hereby incorporated by reference in its entirety.

### TECHNICAL FIELD

The present disclosure relates generally to the field of display equipment and, in particular, to an integrated module and display equipment including the integrated module.

### BACKGROUND

With development of high technology, an increasing number of smart products enter household life. These smart products are having increasingly rich functions as they meet an increasing number of user demands. Due to the abundance of functions, a smart product may include an increasing number of functional devices. Space for laying out various functional devices has to be provided. When these functional devices are scattered at various locations in the smart product, for example, some on the back of the smart product and others below the smart product, more space is required for placing the devices, the distribution of which may also be messy. In addition, as functional devices of different smart products are mostly in different locations, maintenance becomes cumbersome in case of a fault.

### SUMMARY

According to a first aspect of embodiments of the present disclosure, an integrated module includes: a module housing having a transmission hole; an audio input component located in the module housing; and an integrated component located in the module housing, the integrated component including multiple functional devices of different types; wherein the transmission hole is provided for a transmission line that establishes an electrical connection with at least one of the audio input component or the integrated component to pass through.

According to a second aspect of embodiments of the present disclosure, display equipment includes: a main body including a display; and an integrated module detachably connected to the main body. The integrated module includes: a module housing having a transmission hole; an audio input component located in the module housing; and an integrated component located in the module housing, the integrated component including multiple functional devices of different types; wherein the transmission hole is provided for a transmission line that establishes an electrical connection with at least one of the audio input component or the integrated component to pass through.

The above general description and detailed description below are exemplary and explanatory, and do not limit the present disclosure.

### BRIEF DESCRIPTION OF THE ACCOMPANYING DRAWINGS

The accompanying drawings, which are incorporated in and constitute a part of this specification, illustrate embodiments consistent with the present disclosure and, together with the description, serve to explain the principles of the present disclosure.

FIG. 1 is an unfolded view of an integrated module according to an exemplary embodiment.

FIG. 2 is a diagram of a module housing in an integrated module according to an exemplary embodiment.

FIG. 3 is a diagram of a first circuit board and a second circuit board in an integrated module according to an exemplary embodiment.

FIG. 4 is a diagram of a first circuit board and a second circuit board in an integrated module according to an exemplary embodiment.

FIG. 5 is an unfolded view of an integrated module according to an exemplary embodiment.

FIG. 6 is a schematic diagram of locations of an infrared collector, breathing lights, a button, and a connector located on a second circuit board in an integrated module according to an exemplary embodiment.

FIG. 7 is a schematic diagram of display equipment according to an exemplary embodiment.

FIG. 8 is a schematic diagram of a television according to an exemplary embodiment.

FIG. 9 is a schematic diagram of a control circuit of an integrated module in display equipment according to an exemplary embodiment.

FIG. 10 is a schematic diagram of a control circuit of breathing lights in display equipment according to an exemplary embodiment.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the present disclosure. Instead, they are merely examples of apparatuses and methods consistent with aspects related to the present disclosure as recited in the appended claims.

An indicator light, an infrared head, a button, a voice collector, etc., may be placed separately on an area such as an underside, a back side, etc., of a smart product, such as a TV, a computer, etc., as a part or an individual component. Consequently, when there are a large number of parts scattered on the smart product, too much space may be required to place the respective parts. Moreover, excessive material may lead to cumbersome after-sales maintenance.

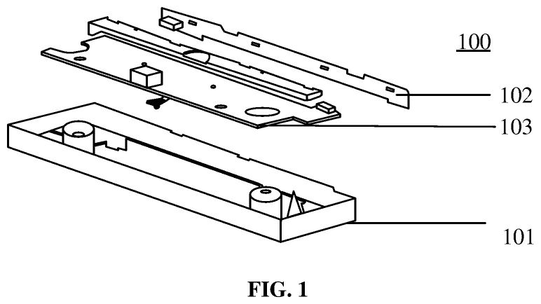

Embodiments of the present disclosure provide an integrated module to save space occupied by various functional devices on a smart product. FIG. 1 is an unfolded view of an integrated module 100 according to an exemplary embodiment. As shown in FIG. 1, the integrated module 100 includes a module housing 101, an audio input component 102, and an integrated component 103.

The module housing 101 has a transmission hole.

The audio input component 102 is located inside the module housing 101.

The integrated component 103 is located inside the module housing 101. The integrated component 103 may include multiple functional devices of different types.

The transmission hole is provided for a transmission line to pass through. The transmission line is for establishing an electrical connection with the audio input component 102 and/or the integrated component 103.

The integrated module 100 may be applied to electronic equipment, including a TV, a computer, a printer, a smart phone, etc. Multiple functional devices or components on the electronic equipment may be integrated inside a housing, forming an integrated module, thereby improving visual effect and reducing space occupied.

The module housing 101 may serve to accommodate various components or various functional devices. The module housing 101 may have a regular shape or a nearly regular shape, such as a cuboid or an approximate cuboid. The module housing 101 may have any other shape, which is not limited herein. In some embodiments, to facilitate layout and mounting, the module housing 101 may have a cuboid or an approximate cuboid, such as a cuboid 145 mm long, 32.3 mm wide, and 13.7 mm high.

The module housing 101 may be movably connected to electronic equipment. That is, the module housing 101 may be separated from the electronic equipment. Thus, the module housing 101 may be connected to the electronic equipment such as by screw, snap, etc. A movable connection may facilitate subsequent maintenance and management.

In addition, for ease of installation and portability, the module housing 101 may be made of light-weight wear-resistant material such as plastic, metal, etc.

In an embodiment, the module housing 101 includes a light emitting device, and light emitted by the light emitting device is to be transmitted to the outside. Accordingly, the module housing 101 may be made of transparent material that allows light to pass through. In an embodiment, light output may be implemented by providing an opening on the module housing 101. For a functional device requiring light of a specific wave band, the module housing 101 may be made of material that allows light of the specific wave band to pass through, such as material that allows infrared light or ultraviolet light to pass through.

In an embodiment, the transmission hole on the module housing 101 may serve to allow a functional device or component placed in the module housing 101 to establish an electrical connection with a main body of the electronic equipment through the transmission line, thereby implementing control of the functional device or component placed in the module housing 101. The main body of the electronic equipment may be, e.g., a motherboard in the electronic equipment for mounting various main chips.

In an embodiment, a functional device or component may not have a wireless transmission function, and a wired transmission is fast and stable. The functional device or component placed in the module housing 101 may be connected to a main body of the electronic equipment using a wire. In another embodiment, the connection may be wireless, which is not limited herein.

In an embodiment, the transmission hole may serve for a transmission line from any functional device or component in the module housing 101 needing an electrical connection to pass through. In addition, given that a functional device or component may be laid out in the module housing 101 along different orientations, different transmission holes may be provided for transmission lines from functional devices or components spaced apart to pass through.

In an embodiment, the transmission hole may be provided along a direction in which the module housing 101 establishes a connection with the electronic equipment. That is, the transmission hole may be provided at a location on the module housing 101 that is adjacent to the electronic equipment. For example, when the module housing 101 is provided below the electronic equipment, for ease of wiring, the transmission hole may be provided atop the module housing 101. When the module housing 101 is provided to the left of the electronic equipment, the transmission hole may be provided on the right side of the module housing 101.

In an embodiment, the transmission hole may be the entire surface where the module housing 101 establishes a connection with the electronic equipment. That is, no housing is provided for the surface where the module housing 101 establishes a connection with the electronic equipment, leaving the surface completely open. A transmission line from a functional device or component may pass directly through the open surface of the module housing 101, and then be connected to the main body of the electronic equipment.

In an embodiment, the transmission hole may include a movable gate structure. In this way, after the integrated module is assembled, the transmission hole may be closed by closing the movable gate, protecting an internal structure of the integrated module.

In an embodiment, the audio input component 102 may be a component that collects an audio signal, such as a microphone, a pickup, etc. When being placed in the module housing 101, the audio input component 102 may be connected to the main body of the electronic equipment through a transmission line passing through the transmission hole. With an audio signal collected by the audio input component 102, a user may be allowed to control the electronic equipment through voice. Correspondingly, a program for recognizing an audio signal may be stored in a voice recognition chip on the electronic equipment, implementing voice recognition, and sending a control instruction corresponding to a recognition result.

In an embodiment, a plurality of sound receivers, such as pickups, may be provided in the audio input component 102 along a line, with fixed spacing in between, for collecting audio signals. The fixed spacing may be set according to the size of the integrated module 100. For example, when a length of the integrated module 100 is 100 cm, the fixed spacing may be set to be within a range of 10 mm to 120 mm. The spacing may be set to reduce crosstalk of sound. The size of the spacing may be determined jointly according to a rule of thumb, or a rule of thumb and a layout requirement. The number of the sound receivers may be determined as needed.

In an embodiment, the number of the sound receivers may be determined based on the size of the electronic equipment, the voice recognition effect, and the computing power of a processor. The more sound receivers, the more resources of the processor are consumed. While a fair voice recognition effect is achieved, fewer sound receivers may be selected to save the computing power of the processor. In an embodiment, the number of the sound receivers may be 4, as determined according to a comprehensive consideration of a rate of occupation of resources of the processor as well as a recognition rate acquired by an actual measurement of the voice effect, which is not limited herein.

In an embodiment, a dust screen may be provided on a pickup hole of a pickup as a sound receiver. Accuracy in collecting an audio signal may be improved by reducing dust entering a pickup, thereby increasing the service life of the pickup.

In an embodiment, a sound hole may be provided on a surface of the module housing 101 facing a sound receiver in the audio input component 102, for collecting a clearer audio signal through the sound hole, maximizing accuracy in audio signal collection.

The integrated component 103 may be a component formed by integrating multiple functional devices of different types on one circuit board.

The functional devices may include a light, a button, and various sensors or connectors. When being placed in the module housing 101, the integrated component 103 may be connected to the main body of the electronic equipment through the transmission line passing through the transmission hole. That is, the circuit board on which the multiple functional devices of different types are located may be connected electrically to the motherboard in the electronic equipment. In this way, various applications may be implemented through information interaction between the functional devices in the integrated component and a main chip.

To collect an accurate audio signal, a great number of sound receivers or microphones may be provided in the audio input component 102. The audio input component 102 and other functional devices of different types may be provided separately, avoiding a bulk circuit board caused by providing all functional devices on the same circuit board.

Another functional device, such as an audio output component, an image collecting component, etc., may be provided in the module housing 101, which is not limited herein.

In the embodiments, an audio input component and an integrated component including multiple functional devices of different types are provided in a same module housing, forming an integrated module. In this way, by integrating, in one module housing, multiple functional devices that would have been scattered here and there, space occupied by layout of the functional devices may be reduced. In addition, various functional devices are allowed to be managed in a standardized mode, facilitating subsequent maintenance, saving time spent by maintenance personnel looking for a mounting location of a functional device in different products or for different models.

In an embodiment, the transmission hole may be located on a first housing of the module housing 101. The first housing may be the surface where the module housing 101 establishes a connection with the electronic equipment, i.e., the surface closest to the main body of the electronic equipment. When the module housing 101 is a cuboid provided under the main body of the electronic equipment, the first housing may be a top surface of the cuboid module housing.

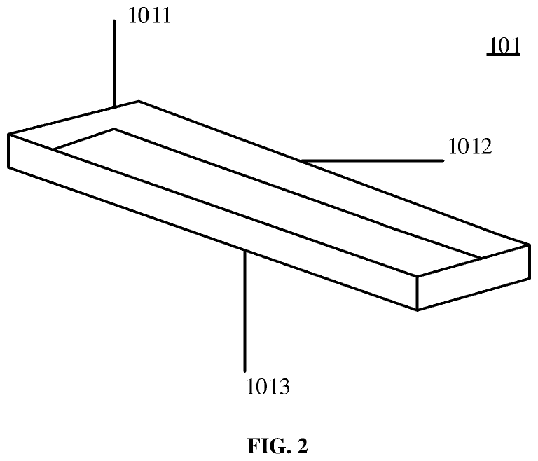

FIG. 2 is a diagram of the module housing 101 (FIG. 1) according to an exemplary embodiment. In the embodiment, the module housing 101 is a cuboid module housing. As shown in FIG. 2, when the transmission hole is provided on a first housing 1011, and the first housing 1011 is the surface where the top of the cuboid module housing 101 is located, a housing in the cuboid module housing 101 adjacent to the first housing 1011 may be a second housing 1012. A third housing 1013 may be another housing adjacent to the second housing 1012. In the cuboid module housing 101, the first housing 1011 and the third housing 1013 may be provided as parallel opposite surfaces. A module housing of a regular shape may be easy to manufacture and easy to lay out due to overall tidiness thereof.

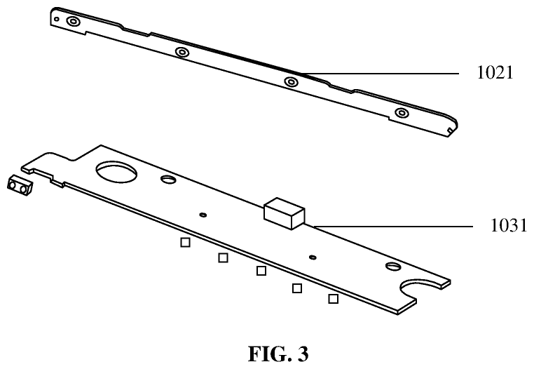

FIG. 3 is a diagram of a first circuit board 1021 and a second circuit board 1031 in the integrated module 100 (FIG. 1) according to an exemplary embodiment. As shown in FIG. 3, the audio input component may be mounted on the first circuit board 1021 and face a second housing of the module housing. The second housing may be adjacent to the first housing. The integrated component may be mounted on the second circuit board 1031 and face a third housing of the module housing. The third housing may be another housing adjacent to the second housing.

In an embodiment, the first circuit board 1021 and the second circuit board 1031 may be fixed inside the module housing to avoid impact caused by displacement, and ensure normal optical paths of various optical devices. Modes in which the first circuit board 1021 and the second circuit board 1031 are fixed are further described below.

In an embodiment, there may be a sound hole on the second housing. The audio input component may be provided facing the second housing of the module housing having the sound hole, which helps collecting a clearer audio signal. By providing the audio input component on the first circuit board, effective unified control over the large number of sound receivers included in the audio input component may be implemented.

In an embodiment, the audio input component may face a housing with a sound hole, which may be any housing in the module housing. Moreover, for a clear audio signal, the housing with the sound hole may have to face a user. That is, the second housing may be a housing with a sound hole and facing the user.

In an embodiment, the first circuit board may be adhered to the second housing with the sound hole. A sound receiver included in the audio input component mounted on the first circuit board may be provided to be aligned with the sound hole. Thus, by being directly adhered to the housing, the first circuit board occupies less layout space. Moreover, the sound hole and the sound receiver are in direct contact, facilitating audio signal collection.

In an embodiment, mounting the integrated component on the second circuit board ensures simultaneous electrical connection of a plurality of functional devices during operation, as well as reducing space occupied corresponding to layout on different circuit boards.

Since the integrated component may include a large number of functional devices, the volume of the second circuit board may be large. In this case, if the second circuit board is also provided on the side housing such as the second housing, there may be an increased height of the module housing, which may not be beneficial for layout. To save layout space, the second circuit board may be parallel to the third housing, and include a first outer surface facing the third housing. The first outer surface may be provided with at least one mounting location.

In an embodiment, the second circuit board may have a board-shape structure, and include two surfaces provided oppositely, namely, a first outer surface, and a second outer surface facing the first housing and opposite to the first outer surface. When the first outer surface faces the third housing, the second outer surface may face the first housing.

Thus, a board surface on the second circuit board provided with a large number of functional devices may be provided parallel to the third housing. Accordingly, the overall height of the module housing will not increase significantly.

The second circuit board being parallel to the third housing may include: the second circuit board being parallel to, but not in touch with, the third housing, i.e., there may be a gap between the second circuit board and the third housing, or the second circuit board being parallel to and in touch with the third housing, i.e., the second circuit board and the third housing may be connected to each other tightly with no gap in between. For example, the second circuit board may be adhered to the third housing, with no space gap in between.

In an embodiment, when the second circuit board is parallel to, but not in touch with, the third housing, a mounting location may be provided on the surface of the second circuit board facing the third housing. In this way, some functional devices may be provided at mounting locations on the surface of the second circuit board facing the third housing, avoiding a bulk second circuit board caused by providing all functional devices in the integrated component on one side of the second circuit board.

In an embodiment, the second circuit board may be secured to the third housing by screw. That is, the second circuit board may be secured to the third housing by screw connecting the second circuit board to the third housing. The screw mode may allow some space between the second circuit board and the third housing. Accordingly, a mounting location may be provided on the surface of the second circuit board facing the third housing of the module housing.

In an embodiment, the second circuit board may be connected to a fourth housing and a fifth housing by screw. Accordingly, one end of the second circuit board may be secured to the fourth housing, and the other end of the second circuit board may be secured to the fifth housing. The fourth housing may be a housing adjacent to both the first housing and the third housing. The fifth housing may be a housing adjacent to both the second housing and the third housing. The fourth housing and the fifth housing may be provided parallel and opposite to each other. In this way, it may be ensured, through the height set by the screw connected to the fourth housing and the fifth housing, that a mounting location may be provided on the surface of the second circuit board facing the third housing.

In an embodiment, the second housing may be provided with an opening for outputting light. The opening may be provided on the second housing for transmitting light emitted by a light emitting device to the outside, so as to be visually perceived by a user. To facilitate visual perception by the user, light may be emitted facing a user, or sideways to the user. Since the second housing faces the user, light may be transmitted by directly providing an opening on the second housing, ensure clarity of an audio signal collected while allowing the user to visually experience a light signal sent by the electronic equipment.

In an embodiment, the second housing may be made of transparent material, such as transparent resin. When the second housing is made of transparent material, light may show at a light emitting location even if no opening is provided on the second housing.

In an embodiment, a light emitting device is located on the second circuit board, and the first circuit board is located on the second housing. Light emitted by the light emitting device may be blocked, thereby failing to be transmitted outside the second housing. Accordingly, at least one notch may be provided on the first circuit board, and the notch may face the opening. In this way, light emitted by the light emitting device on the second circuit board may be transmitted to a notch on the first circuit board, then transmitted to the opening on the second housing, thereby to the outside, implementing light transmission without occupying too much space.

In the embodiment, the notch may be provided on the first circuit board at the location facing a light emitting surface of the light emitting device, thereby reducing waste of light caused by some light not being transmitted to the outside due to deflection of an optical path.

In an embodiment, the notch on the first circuit board may be located at either end of the first circuit board, or in the middle of the first circuit board. For example, when breathing lights are evenly distributed in a continuous area on the second circuit, the notch may be provided on the first circuit board in the middle, facing light emitting surfaces of light emitting devices. In this way, light may be output corresponding to layout of the breathing lights, reducing loss. Also for example, when two blocks of breathing lights are distributed respectively on both ends of the second circuit board, two notches may be provided on the first circuit board respectively at two ends, to conduct light emitted by breathing lights at corresponding locations.

The breathing lights are divided into two blocks distributed respectively on two ends of the second circuit board, reducing difficulty caused by laying out a large number of breathing lights, facilitating layout of another functional device. Meanwhile, notches may be provided at both ends of the first circuit board, reducing a height of the first circuit board, reducing a volume of the integrated module, saving cost.

In an embodiment, the multiple functional devices may include a breathing light. There may be a light guide device between the breathing light and the notch.

A breathing light may be a light which is controlled to turn from bright to dark, presenting a breathing effect. A breathing light may be one of a single color or multiple colors. A single-color breathing light may present monochromatic light (light of one color). A multicolored breathing light may present polychromatic or multicolored light. That is, a light emitting device herein may be a breathing light.

The light guide device may serve to conduct light emitted by a breathing light. The light guide device may include a light guide column or a light guide sheet. A light guide device is provided between a breathing light and a notch, reducing light divergence, facilitating light conduction. To save layout, the light guide device may be selected as a light guide sheet.

The light guide device may be secured inside the module housing, to reduce optical path disorder and damage caused by displacement. The light guide device may be secured to the second circuit board, to reduce a distance between the light guide device and a breathing light, facilitating light conduction. For example, the light guide device may be secured to the second circuit board by a locating column, i.e., onto the surface of the second circuit board facing the second housing.

To prevent local light leakage, a device made of light-shielding material may be adhered to the light guide device. For example, a light-shielding glue may be adhered to both ends of the light guide device.

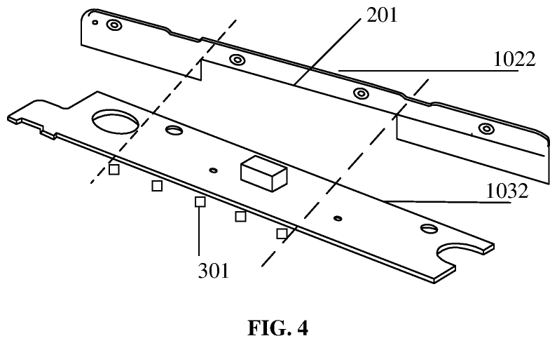

FIG. 4 is a diagram of a first circuit board 1022 and a second circuit board 1032 in an integrated module according to an exemplary embodiment. As shown in FIG. 4, a length of a notch 201 on the first circuit board 1022 may be the same as a length of multiple breathing lights 301 lined up on the second circuit board 1032.

The breathing lights 301 lined up on the second circuit board 1032 may emit a strip of light, i.e., forming a light strip. The length of the light strip may be determined by the number and layout of the breathing lights 301.

When being provided on the second circuit board 1032 in a line, the breathing lights 301 may be spaced evenly. In this way, when the breathing lights 301 are of multiple colors, various colors in the presented light strip may be distributed evenly, improving a visual effect.

Light emitted by the breathing lights 301 may have to be transmitted to the outside so as to be perceived by a user. Light may be transmitted to the second housing through the notch 201 on the first circuit board 1022, thereby to the outside. The length of the notch 201 on the first circuit board 1022 may control a length of a light strip displayed to the outside. In this way, the length of the notch 201 on the first circuit board 1022 may be set to be the same as the length of multiple breathing lights 301 lined up on the second circuit board 1032, which may reduce material removed for generating the notch 201 on the first circuit board 1022, while ensuring that the light strip formed by the breathing lights 301 is fully perceived by the user.

In an embodiment, the breathing light may be located at the at least one mounting location, with a light-emitting surface facing the second housing. The at least one mounting location on the second circuit board may be located on a surface of the second circuit board facing the third housing. For example, the integrated module may be mounted at the lower end of the electronic equipment. A mounting location may be at a lower end of the integrated module. Thus, a breathing light mounted on the mounting location may show, through the opening on the second housing and the corresponding notch on the first circuit board, a light strip at the lower end of the second housing of the module housing of the integrated module facing the user. In this way, light interference to a functional device requiring light, as caused by a light strip located in the middle or at the upper end of the integrated module, may be reduced, improving visual experience.

The mounting location may provide an electrical connection for a breathing light. As the mounting location faces the third housing, a light emitting surface of a breathing light provided directly on the mounting location may face the third housing instead of the second housing. As a result, emitted light may not reach the outside through the opening on the second housing and the corresponding notch on the first circuit board. Thus, a light emitting surface of a breathing light may need to face the second housing.

In an embodiment, a light emitting surface of a breathing light may face the second housing by changing a direction along which the light emitting surface is installed on a mounting location, or changing an orientation of a lead when being welded, which is not limited herein. By having a light emitting surface of a breathing light face the second housing, as much light emitted by the breathing light as possible may reach the outside through the opening on the second housing and the corresponding notch on the first circuit board, reducing loss.

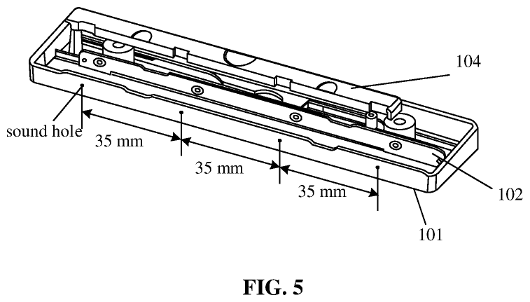

FIG. 5 is an unfolded view of an integrated module according to an exemplary embodiment. As shown in FIG. 5, a light-shielding plate 104 may be provided on an inner side of the first housing. The light-shielding plate 104 may cover a surface of the first circuit board facing the first housing. An area of the light-shielding plate 104 may be no less than an area of the surface of the first circuit board facing the first housing.

For illustrative purposes, the first circuit board may be shown to be separated from the second housing. In the actual integrated module, the first circuit board may be adhered to the second housing having a sound hole. The location of the sound hole on the second housing may correspond to the location of the sound receiver on the first circuit board. As shown in FIG. 5, for example, when sound receivers are lined up on the first circuit board at spacing of 35 mm, sound holes may as well be lined up on the second housing at the spacing of 35 mm.

The first circuit board may include a side surface. The side surface may be perpendicular to a surface adhesively connected to the second housing, and faces the first housing.

The surface adhesively connected to the second housing may be a board surface of the first circuit board. The board surface of the first circuit board may be adhesively connected to the second housing, and provided with an audio input component.

The light-shielding plate 104 may cover the side surface of the first circuit board. For example, as shown in FIG. 5, the light-shielding plate 104 may cover the first circuit board from above, and be located inside the first housing, serving to further secure the first circuit board, preventing movement of the first circuit board caused by improper adhesion or deterioration of adhesiveness over time.

Further, an area of the light-shielding plate 104 may be set to be equal to or greater than an area of the side surface. In this way, part of the light-shielding plate 104 may cover the side surface of the first circuit board from above. The other part of the light-shielding plate 104 may cover a location between the first circuit board and the second circuit board. In this case, light may be shielded partly, reducing leakage caused by light being emitted from above.

In an embodiment, to better shield light, the light-shielding plate 104 may be made of light-shielding material.

The functional devices may include an infrared collector. A collecting surface of the infrared collector may face the second housing. The second housing may be made of material that allows infrared light to pass through.

The infrared collector may serve to collect an infrared signal and convert it into an electrical signal. After the infrared signal is transmitted to the main chip, the electronic equipment may be controlled based on the received infrared signal. The collecting surface of the infrared collector may be a receiving head of the infrared collector.

For example, the electronic equipment may be a TV. The infrared collector may collect infrared light emitted by a remote control. Accordingly, a channel as well as a working state of the TV may be changed.

As mentioned above, when the second housing faces the user, infrared light may be collected more quickly by providing the collecting surface of the infrared collector to face the second housing. The second housing may be made of material that allows infrared light to pass through, ensuring as much infrared light as possible to pass through the second housing and enter the module housing, so as to be collected by the infrared collector.

In an embodiment, the collecting surface of the infrared collector may be made to face the second housing as follows. The infrared collector may be mounted directly on a surface of the second circuit board facing the second housing. In this case, the collecting surface (i.e., the receiving head) of the infrared collector may directly face the second housing. The infrared collector may be provided on the surface of the second circuit board facing the first housing by being sunk into the board or through a special welding process. The collecting surface (i.e., the receiving head) of the infrared collector may be perpendicular to the first housing and face the second housing.

In an embodiment, an infrared signal may be collected by providing an opening at a location of the second housing the collecting surface of the infrared collector faces. In this case, there is no limitation on material of the second housing.

In addition, since the first circuit board is provided on the second housing, when a collecting surface of the infrared collector faces the second housing, if the collecting surface of the infrared collector faces the mounting location where the first circuit board is mounted, the first circuit board may block infrared light. In view of this, an infrared collector may be provided at either ends of a surface of the second circuit board facing the second housing. That is, the length of the second circuit board may be provided to be greater than the length of the first circuit board. Accordingly, in a front view of the second housing, the surface of the second circuit board facing the second housing may extend beyond the first circuit board at both ends. Infrared collectors may be provided at locations on the surface of the second circuit board facing the second housing that extend beyond the first circuit board, i.e., at both ends of the surface of the second circuit board facing the second housing, thereby ensuring that as much infrared light as possible is collected by the infrared collectors.

In an embodiment, the functional devices may include a connector. The connector may be located on the second outer surface of the second circuit board. The connector may be connected to the transmission line passing through the transmission hole. The connector may be configured to provide an electric connection for the second circuit board. The second outer surface may be opposite to the first outer surface.

In an embodiment, the connector may be an electrical connector for electrically connecting two active devices through a cable. The connector may be a Universal Serial Bus (USB) interface, a serial communication interface, or a parallel communication interface (such as an 8-pin connector).

In an embodiment, the first circuit board and the second circuit board may be respectively connected electrically to the motherboard using respective connectors. That is, the first circuit board and the second circuit board may be provided with respective connectors. Using separate connectors may help information transmission, and provide prompt response, allowing multiple circuit boards to work at the same time. The present disclosure does not limit the type and the number of connectors of circuit boards.

In an embodiment, a connector may be provided on a surface of the second circuit board facing the first housing, which facilitates wiring and reduces the length of a transmission line. That is, the connector does not have to be bent and may be directly connected to the transmission line passing through the transmission hole on the first housing, and then to the motherboard of the electronic equipment through the other end of the transmission line, to establish an electrical connection.

In an embodiment, the functional devices may include a button. The button may be located on the second circuit board. A control surface of the button may face the third housing. The control surface of the button may be a touch surface, i.e., the surface where the button is triggered.

The button may be a mechanical button or a capacitive button. When a mechanical button is pressed, a change in the structure of the button may cause a change in the state of a circuit, thereby changing an output electrical signal. Touch of a capacitive button may cause a change in capacitance, which may be detected by the circuit. The circuit may then send, to the motherboard, key value data corresponding to the change in capacitance.

The mechanical structure of the mechanical button may change. Accordingly, when touch is required, the control surface of the button may be made to face the third housing, and then an opening may be provided on the third housing, allowing a user to trigger the button through the opening on the third housing.

The control surface of the capacitive button may face, and stay seamlessly against, the third housing, allowing a user to trigger, by touching the third housing, the capacitive button that is against the third housing. When the capacitive button is selected, no opening has to be provided on the third housing. In this way, the button may be integrated in the integrated module as well, further reducing occupation of layout on the electronic equipment.

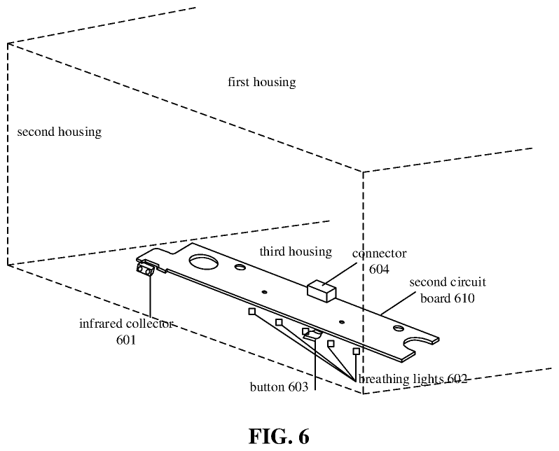

FIG. 6 is a diagram of locations of an infrared collector 601, breathing lights 602, a button 603, and a connector 604 located on a second circuit board 610 in an integrated module according to an exemplary embodiment. As shown in FIG. 6, the infrared collector 601 may be located at both ends on the surface of the second circuit board 610 facing the second housing, allowing a collecting surface of the infrared collector 601 to face the second housing directly. Accordingly, infrared light passing through the second housing may be collected faster. The breathing lights 602 may be lined up on mounting locations of the second circuit board 610 facing the third housing.

Light-emitting surfaces of the breathing lights 602 may face the second housing, specifically the opening of the second housing as well as the notch on the first circuit board on the second housing. The button 603 may be provided on the surface of the second circuit board 610 facing the third housing. The connector 604 may be provided on the surface of the second circuit board 610 facing the first housing.

In this way, various functional devices may be distributed on several sides of the second circuit board, reducing the volume of the second circuit board, thereby reducing the volume of the entire integrated module, facilitating installation and layout.

With embodiments herein, an audio input component and an integrated component including multiple functional devices of different types are provided in a same module housing, forming an integrated module. In this way, by integrating, in one module housing, multiple functional devices that would have been scattered here and there, space occupied by layout of the functional devices may be reduced. In addition, integrating multiple functional devices in one module housing facilitates subsequent maintenance. That is, when a functional device in the integrated module fails, only the integrated module has to be detached and maintained separately, instead of moving the entire device for maintenance, which also facilitates maintenance, as well as saving time spent by maintenance personnel looking for a mounting location of a functional device in different products or for different models.

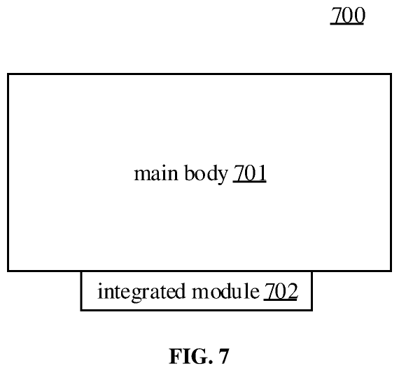

Embodiments of the present disclosure also provide display equipment, to save space occupied by various functional devices on a smart product. FIG. 7 is a schematic diagram of display equipment 700 according to an exemplary embodiment. The display equipment 700 may be large-screen display equipment, such as a large-screen computer, large-screen teaching equipment, a TV, etc.

As shown in FIG. 7, the display equipment 700 may include a main body 701 and an integrated module 702. The main body 701 may include a display. The integrated module 702 may be detachably connected to the main body 701.

In FIG. 7, the integrated module 702 is mounted below the main body 701 of the display equipment 700. The integrated module 702 may also be mounted on the left side of the main body 701, on the right side of the main body, above the main body 701, etc.

In an embodiment, to facilitate wiring, the integrated module 702 may be mounted according to a location of a surface on the main body 701 of the display equipment 700 having a through hole. For example, when there is a through hole in a bottom surface of the main body 701 of the display equipment 700, the integrated module 702 may be mounted below the main body 701 of the display equipment 700. When there is a through hole in a left end surface of the main body 701 of the display equipment 700, the integrated module 702 may be mounted on the left side of the main body 701 of the display equipment 700, so on and so forth.

In this way, various functional devices and components in display equipment may be transferred from a main body of the display equipment to a same integrated module, effectively reducing space occupied by a plurality of scattered functional components, improving visual experience, facilitating subsequent maintenance, saving time spent by maintenance personnel looking for a mounting location of a functional device in different products or for different models.

In an embodiment, the main body 701 may further include a motherboard. Both the motherboard and the display may be located inside an equipment housing. The equipment housing may be provided with a through hole. The transmission line of the integrated module 702 may be connected to the motherboard through the through hole. Functional devices in the integrated module 702 may be controlled through a signal sent by the motherboard.

In an embodiment, the main body 701 may be the body of the display equipment 700. The main body 701 may include an equipment housing, as well as a motherboard and a display located inside the equipment housing.

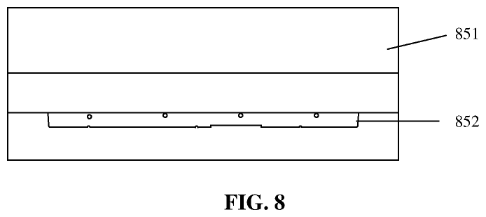

For example, the display equipment may be a TV. FIG. 8 is a schematic diagram of a TV according to an exemplary embodiment. As shown in FIG. 8, the TV may include a TV housing 801. There may be a through hole in a surface of the TV housing 801. An integrated module 802 may be connected to the TV housing 801 through a screw in the through hole.

Through layout of the integrated module 802, light emitted by a breathing light on the integrated module 802 located below the TV housing 801 may be emitted from the front of the TV. A user sitting in front of the TV may visually experience a strip of light, improving user experience greatly.

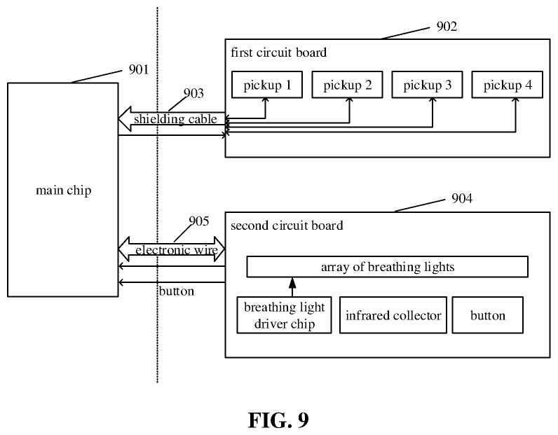

FIG. 9 is a schematic diagram of a control circuit of an integrated module in display equipment according to an exemplary embodiment. For example, the display equipment may be a TV. The TV may further include a motherboard provided with a main chip 901.

The motherboard may be located inside a TV housing. The motherboard may be connected to an audio input component on a first circuit board 902 in the integrated module through a cable 903 with a shielding function. The cable 903 may pass through the transmission hole of the first housing on the module housing of the integrated module. The motherboard may be connected to a second circuit board 904 in the integrated module through an electronic wire 905 passing through the transmission hole.

The motherboard may be configured to provide a control signal to the audio input component as well as a functional device in the integrated component, and to receive data transmitted by the audio input component as well as a functional device in the integrated component.

The main chip 901 may be provided on the motherboard for sending various control instructions, and receiving various data, such as audio data. The motherboard may be connected to the integrated module as follows. The main chip 901 may be connected to the audio input component located on the first circuit board 902 in the integrated module, or to a functional device on the second circuit board 904 in the integrated module.

The electronic wire 905 may be various signal transmission lines, such as an Inter-Integrated Circuit (I2C) bus. The motherboard may be connected to the second circuit board 904 by the electronic wire 905. The electronic wire 905 may be applied to most connectors, and may be compact, meeting a requirement of miniaturization of the structure.

Compared to the electronic wire 904, a connector of a Flexible Flat Cable (FFC) with a shielding function may be smaller in size, meeting a requirement of miniaturization of the structure as well. In addition, a shielding layer of the cable 903 with the shielding function may reduce outward radiation of a clock signal of a microphone or a pickup, facilitating interference test.

In an embodiment, the audio input component may match different machines or different motherboards. Radiation may differ depending on a machine structure. Therefore, an FFC may be applied to wider scenes thanks to its small volume and shielding function.

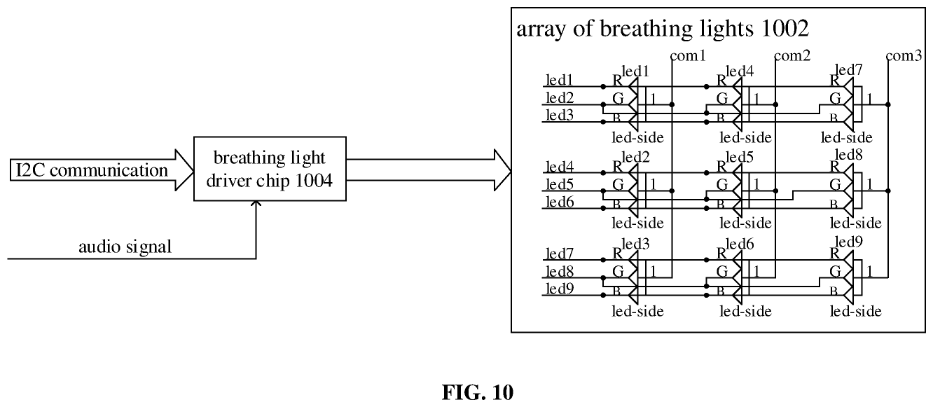

FIG. 10 is a schematic diagram of a control circuit of breathing lights in display equipment according to an exemplary embodiment. As shown in FIG. 10, an array of breathing lights 1002 and a breathing light driver chip 1004 may be mounted on the second circuit board where the integrated module is located. The breathing light driver chip 1004 may output signaling in an array scan mode, and may drive the breathing lights 1002 to emit light at the same time. The number of breathing lights may be provided according to the size of space.

For standardization that suits various types of TVs and facilitates mass production, the breathing lights 1002 may be provided to distribute over a same length regardless of the number of the breathing lights. For example, 9 breathing lights may line up on the second circuit board over the same length as 3 breathing lights do. Then, spacing among the 9 breathing lights will be less than spacing among the 3 breathing lights.

The breathing light driver chip 1004 may support I2C communication. The array of breathing lights 1002 may be controlled to switch among different lighting effects according to an I2C command sent by the main chip on the motherboard. Lighting effects among which the array of breathing lights 1002 switches may be preset. The breathing light driver chip 1004 may also output, according to a collected audio signal, a lighting effect that varies with sound, enriching scenes of application of breathing lights.

In the embodiments, an audio input component and an integrated component including multiple functional devices of different types are provided in a same module housing, forming an integrated module. In this way, by integrating, in one module housing, multiple functional devices that would have been scattered here and there, space occupied by layout of the functional devices may be reduced. In addition, control is achieved by electrically connecting functional devices in the integrated module to the motherboard of the TV, various functional devices are allowed to be managed in a standardized mode, and the wiring mode and the electrical connection mode may be applied to most types of TVs, facilitating standardized production.

Other embodiments of the present disclosure will be apparent to one skilled in the art after consideration and practice of the disclosure. The application is intended to cover any variation, use, or adaptation of the disclosure following the general principle of the disclosure and including such departures from the disclosure as come within knowledge or customary practice in the art. The above described embodiments are exemplary only, with a true scope and spirit of the disclosure being indicated by the appended claims.

The disclosure is not limited to the exact construction that has been described above and illustrated in the accompanying drawings. Various modifications and changes may be made without departing from the scope of the disclosure. It is intended that the scope of the disclosure be limited only by the appended claims.

What is claimed is:

1. An integrated module, comprising:
a module housing having a transmission hole;
an audio input component located in the module housing; and
an integrated component located in the module housing, the integrated component comprising multiple functional devices of different types;
wherein the transmission hole is provided for a transmission line that establishes an electrical connection with at least one of the audio input component or the integrated component to pass through.

2. The integrated module of claim 1, wherein:
the transmission hole is located on a first housing of the module housing;
the audio input component is mounted on a first circuit board and faces a second housing of the module housing, the second housing being adjacent to the first housing; and
the integrated component is mounted on a second circuit board and faces a third housing of the module housing, the third housing being adjacent to the second housing.

3. The integrated module of claim 2, wherein:
the second housing is provided with an opening for outputting light;
the first circuit board is provided with at least one notch facing the opening; and
the multiple functional devices comprise a breathing light, a light guide device being between the breathing light and the notch.

4. The integrated module of claim 3, wherein a length of the notch on the first circuit board is same as a length of a line of a plurality of breathing lights on the second circuit board.

5. The integrated module of claim 3, wherein:
the second circuit board is parallel to the third housing and comprises a first outer surface facing the third housing, the first outer surface being provided with at least one mounting location; and
the breathing light is located at the at least one mounting location, a light-emitting surface of the breathing light facing the second housing.

6. The integrated module of claim 5, wherein:
the second circuit board further comprises a second outer surface facing the first housing, the second outer surface being opposite to the first outer surface; and
the multiple functional devices comprise a connector located on the second outer surface, the connector being connected to the transmission line passing through the transmission hole, and configured to provide an electric connection for the second circuit board.

7. The integrated module of claim 2, wherein the multiple functional devices comprise an infrared collector, a collecting surface of the infrared collector facing the second housing, wherein the second housing is made of material that allows infrared light to pass through.

8. The integrated module of claim 2, wherein:
the first circuit board is adhered to the second housing;
the second housing has a sound hole; and
the audio input component comprises a sound receiver aligned with the sound hole.

9. The integrated module of claim 8, wherein:
the first circuit board comprises a side surface, the side surface being perpendicular to a surface adhesively connected to the second housing, and facing the first housing; and
a light-shielding plate is provided on an inner side of the first housing, the light-shielding plate covering the side surface of the first circuit board, and an area of the light-shielding plate being no less than an area of the side surface.

10. The integrated module of claim 2, wherein the multiple functional devices comprise a button located on the second circuit board, a control surface of the button facing the third housing.

11. Display equipment, comprising:
a main body comprising a display; and
an integrated module detachably connected to the main body, the integrated module comprising:
a module housing having a transmission hole;
an audio input component located in the module housing; and
an integrated component located in the module housing, the integrated component comprising multiple functional devices of different types;
wherein the transmission hole is provided for a transmission line that establishes an electrical connection with at least one of the audio input component or the integrated component to pass through.

12. The display equipment of claim 11, wherein:
the main body further comprises a motherboard;
the motherboard and the display are located inside an equipment housing provided with a through hole; and
the transmission line of the integrated module is connected to the motherboard through the through hole.

13. The display equipment of claim 11, wherein:
the transmission hole is located on a first housing of the module housing;
the audio input component is mounted on a first circuit board and faces a second housing of the module housing, the second housing being adjacent to the first housing; and
the integrated component is mounted on a second circuit board and faces a third housing of the module housing, the third housing being adjacent to the second housing.

14. The display equipment of claim 13, wherein:
the second housing is provided with an opening for outputting light;
the first circuit board is provided with at least one notch facing the opening; and
the multiple functional devices comprise a breathing light, a light guide device being between the breathing light and the notch.

15. The display equipment of claim 14, wherein a length of the notch on the first circuit board is same as a length of a line of a plurality of breathing lights on the second circuit board.

16. The display equipment of claim 14, wherein:
the second circuit board is parallel to the third housing and comprises a first outer surface facing the third housing, the first outer surface being provided with at least one mounting location; and
the breathing light is located at the at least one mounting location, a light-emitting surface of the breathing light facing the second housing.

17. The display equipment of claim 13, wherein the multiple functional devices comprise an infrared collector, a collecting surface of the infrared collector facing the second housing, wherein the second housing is made of material that allows infrared light to pass through.

18. The display equipment of claim 13, wherein:
the first circuit board is adhered to the second housing;
the second housing has a sound hole; and
the audio input component comprises a sound receiver aligned with the sound hole.

19. The display equipment of claim 18, wherein:
the first circuit board comprises a side surface, the side surface being perpendicular to a surface adhesively connected to the second housing, and facing the first housing; and
a light-shielding plate is provided on an inner side of the first housing, the light-shielding plate covering the side surface of the first circuit board, and an area of the light-shielding plate being no less than an area of the side surface.

20. The display equipment of claim 13, wherein the multiple functional devices comprise a button located on the second circuit board, a control surface of the button facing the third housing.
